(19) United States
(12) Patent Application Publication
(10) Pub. No.: US 2011/0206842 A1
(43) Pub. Date: Aug. 25, 2011

(54) CVD-Siemens Reactor Process Hydrogen Recycle System

(76) Inventors: Vithal Revankar, Houston, TX (US); Sanjeev Lahoti, Houston, TX (US)

(21) Appl. No.: 12/712,314

(22) Filed: Feb. 25, 2010

(51) Int. Cl. C23C 16/448; C23C 16/00

(52) U.S. Cl. 427/248.1; 118/724

(57) ABSTRACT

A hydrogen recycle process and system for use with chemical vapor deposition (CVD) Siemens type processes is provided. The process results in substantially complete or complete hydrogen utilization and substantially contamination-free or contamination-free hydrogen.

### FIELD OF THE INVENTION

The present invention relates to a hydrogen recycle process/system for chemical vapor deposition (CVD) of polysilicon. In particular, the present invention relates to the substantially complete or complete hydrogen utilization and substantially contamination-free or contamination-free hydrogen recycle process of producing polysilicon chunk materials via the decomposition of gaseous silane precursors.

### BACKGROUND OF THE INVENTION

The production of polysilicon chunk materials via the decomposition of a gaseous precursor compound on a slim rod substrate is a well-known, widely used process commonly referred to as the “Siemens process.” The Siemens process is a combined decomposition/deposition process that comprises: (1) heating one or more rods or filaments (appropriate substrates) covered by a suitable enclosure to allow high temperature, air-tight operation; (2) feeding a precursor material or compound of desired composition (containing silicon) with no or minimal contamination; (3) further heating the enclosed rods or filaments to a desired temperature under an appropriate environment; (4) decomposing the precursor material preferentially on the heated surface of the rods/filaments to form chunk polysilicon on the substrate or the slim rod; (5) recovering or disposing of byproducts; and (6) recovering the polycrystalline silicon grown slim rods without contaminating them.

In typical Siemens processes and reactors, the reactant gas is fed to the rods from a single port resulting in uneven growth. Such uneven gas distribution over the length of the rod further promotes heavy homogeneous nucleation. Such uneven growth and homogeneous nucleation promote eventual reactor failure. Moreover, the rods within typical Siemens process reactors are not individually isolated. As a result, homogeneous nucleation, lower conversion, higher by-products, and uneven growth on the rods is further promoted by uneven radiant heat between the rods and gas precursor distribution.

Known systems utilizing the Siemens process use at least two power supplies hooked to each reactor system. One or more primary power supply is used for heating and maintaining the temperature of the reactor slim rod (i.e., the rods on which the chuck silicon material is deposited) system for gas decomposition/deposition. A secondary power supply is generally necessary at initiation of heating to overcome the electrical resistance of the silicon rod (supply very high voltage, greater than about 26,000 volts typical for the reactor and also the voltage needed dependent upon the length and diameter of the slim rod assembly used). The necessity for a high voltage power supply significantly increases the cost and safety concerns of operating such known reactors.

In some known reactors, rather than use a very high voltage source, a heating finger is introduced into the reaction space and parallel to the deposition rods. To preheat the reactor slim rods to be deposited, the heating finger is lowered into the reaction space in the proximity of the slim rods mounted in the reactor. Once the slim rods to be deposited upon are at the optimum electically conductive condition with temperature, the electrical current can be passed through the carrier rods, and then the heating fingers are removed from the reactor, and the opening in the metallic enclosure is sealed. Such known reactors present further issues with the purity/integrity of the product, throughput, and establishing and maintaining a seal as well as safety, operational and maintenance issues.

According to known common industrial processes, elemental silicon is obtained in the Siemens type reactor, in the form of cylindrical rods of high purity by decomposing silicon halides from the gas phase at a hot surface of the pure and purified silicon filament, the preferred halides being the chlorides, silicon tetrachloride and trichlorosilane. These compounds become increasingly unstable at temperatures above 800° C. and decompose. Homogeneous and heterogeneous nucleation process compete with each other in the reactor, hence silicon deposition, starts at about 800° C. via heterogeneous reaction and this deposition extends to the melting point of silicon at 1420° C. Since the deposition is beneficial only on the slim rods, the inner walls of the decomposition chamber must not reach temperatures near 800° C. in order to prevent wasteful deposition on the chamber walls. In known Siemens process reactors, the reactor walls are generally cooled to prevent such wasteful deposition and also to maintain the structural integrity of the assembly. However, cooling the walls consumes additional energy. A further issue with the cooling of the reactor walls is the thermophoretic deposition of powder particles on the cooled reactor walls. Such deposition is generally weak resulting in the multiple recirculation of the particles in the gas stream. This deposited powder eventually loosens and collapses into the reactor, causing premature failure of the reactor.

The silicon halides used most frequently for the preparation of high purity silicon are silicon tetrachloride and trichlorosilane. These halides will undergo pyrolysis when in contact with the hot surface and deposit elemental silicon. To obtain reasonable and economical yields, however, an excess of hydrogen gas is added to the silicon halide vapor reaction feed gas. Because of its proportionally higher silicon content per unit weight and comparatively lower deposition temperature (i.e., faster kinetics), trichlorosilane will deposit more silicon than silicon tetrachloride and is therefore the preferred material for the Siemens' process for the preparation of polycrystalline silicon using silicon halide process. Silicon halides with less than three chlorine atoms, such as SiH₂Cl₂ and SiH₃Cl, in particular, deposit much more silicon per mole of silicon halide consumed in the reaction but are impractical because they are not readily available and thus less desirable economically. In such known processes, the yield is not more than 20% (±2%) per each pass through the reactor and the by-product gases are very difficult to handle.

Another approach to improved deposition rates is to use mixtures of silane and hydrogen where fast kinetics and lower temperatures assist faster deposition and better conversion. For example, silane (SiH₄) offers itself as an effective silicon precursor and having no chlorine in the molecule improves the silicon to hydrogen ratios of silicon reaction gas mixtures. Silane decomposes above 400° C. forming silicon and hydrogen which is at much lower temperature compared to the trichlorosilane process. The byproducts formed are silane and hydrogen which may be readily recycled.

Typically, the hydrogen stream from the Siemens reactor contains homogeneous reaction dust, unconverted reactant gas, gas related by-products and other impurities. Thus, the hydrogen stream if re-circulated directly may contaminate the polycrystalline silicon rods and therefore, cannot be reused in the process. The loss of hydrogen in the Siemens systems is further an economic drain on the production of polycrystalline silicon rods due to the huge volume and large dilution required. Therefore, a system for purifying and recycling hydrogen gas would be desirable.

### BRIEF SUMMARY OF THE INVENTION

One embodiment of the invention provides an improvement for a CVD-Siemens system including a reactor vessel containing at least one reaction chamber surrounded by a jacket, wherein a pre-heating fluid is circulated in the jacket; one or more electrode assemblies extending into the reaction chamber wherein each electrode assembly comprises a gas inlet, one or more heat transfer fluid inlets/outlets; at least one pair of silicon filaments, the filaments connected to each other at their upper ends with a silicon bridge to form a filament/slim rod assembly, each filament/slim rod assembly enclosed in an isolation jacket; a source of a silicon-bearing gas connected to the interior of the vessel for supplying the gas into the reaction chamber, wherein the reaction chamber includes one or more distributor locations, to produce a reaction and to deposit polycrystalline silicon on the filaments by chemical vapor deposition thereby producing a rod of polycrystalline silicon; a heat transfer system connected to the jacketed reaction chamber to supply heat transfer fluid to preheat the filaments/slim rod assemblies; and a power supply, the improvement comprising a hydrogen recovery and recycle system comprising: a liquid Nitrogen cooling system; a silane condenser; a recycle hydrogen cooler; and a Hydrogen regeneration cooler, a compressor, and one or more interchangers wherein the discharged gas from the reactor is cooled to between about 30 and 40° C., the compressor accepts and compresses the cooled gas to the system requirement pressure, the interchangers cool an off-gas to between −160 and −165° C. using counter flow between cooler and warmer streams, the off-gas stream is further cooled to between −170 and −180° C. using a liquid nitrogen exchanger in the hydrogen regeneration cooler.

Another embodiment of the invention provides a method for recovery, purification and recycle of hydrogen in a CVD Siemens process comprising: collecting off gases from a CVD Siemens process reactor; cooling the off gases; filtering the off gases; compressing the off gases to at least about 25 psig; cooling the compressed off gases to a temperature between about −160 C and −165 C and then cooling the compressed off gases againt to a temperature between about −170 C and −180 C thereby separating condensed impurities from a hydrogen component of the off gases; passing the hydrogen component through absorption beds to remove any argon, hydrocarbons, uncondensed silanes, boron and phosphorous compounds from the hydrogen component to obtain a first filtered hydrogen stream; cryogenically filtering the first filtered hydrogen stream to produce a second filtered hydrogen stream; heating the second filtered hydrogen stream to between about 25 C and 30 C to produce a high purity hydrogen stream; passing the high purity hydrogen stream through a recycle hydrogen filter to remove particles having a size between 0.1 and 0.4 microns to produce a final hydrogen recycle stream; and recycling the final hydrogen recycle stream to the CVD Siemens process reactor.

### DESCRIPTION OF THE DRAWINGS

FIG. 1 is a schematic depicting the chemical vapor deposition system useful in some embodiments of the invention.

FIG. 2 is a schematic depicting a reactor nitrogen cooling/recycle system useful in some embodiments of the invention.

### DETAILED DESCRIPTION

Embodiments of the invention provide a silicon rod production apparatus, having: a reactor vessel containing at least one reaction chamber surrounded by a jacket, wherein a pre-heating fluid is circulated in the jacket; one or more electrode assemblies extending into the reaction chamber wherein each electrode assembly comprises one or more gas inlets, one or more heat transfer fluid inlets/outlets, at least one pair of silicon filaments, the filaments connected to each other at their upper ends with a silicon bridge to form a filament/slim rod assembly, each filament/slim rod assembly enclosed in an isolation heat transfer fluid jacket; a source of a silicon-bearing gas distributed at various points via nozzles to the interior of the vessel for supplying the gas into the reaction chamber to produce a reaction and to deposit polycrystalline silicon on the filament by chemical vapor deposition thereby producing a rod of polycrystalline silicon; a heat transfer system that is connected to the jacketed reaction chamber that supplies heat transfer fluid to preheat the deposition slim rods (onto which chunk silicon will be deposited) and maintains the jacket wall temperature; and a power supply wherein the power supply provided significantly less than about 26,000 volts; wherein the apparatus does not include a heating finger.

The reactor has a thick and thermally cooled base plate. The base plate has cavities to facilitate passage of a heat transfer liquid, gas inlet, diluents inlet, electrode inserts and exhaust port. A metal bell-shaped enclosure which is surrounded by an enclosed channel with a jacket to facilitate passage of a heat transfer liquid over the outside surface of the bell-shaped enclosure. Thin rods of silicon are mounted in a U-shaped configuration on an electrode and are held in place on the base plate. The electrodes are coupled to electrical connectors which pass through the base plate and are tied to an electric power source.

Additional steps in the inventive process include preheating the rods reaction chamber to a temperature at which the silicon filaments become conductive by circulating a heat transfer fluid in the heat transfer system surrounding the slim rods/silicon filaments; heating the silicon filaments to a silicon deposition temperature by applying an electric current from the power supply; feeding a reactant gas stream to the reaction chamber; decomposing at least a part of the reactant gas stream to form silicon; and depositing silicon on the silicon filaments to produce a polycrystalline silicon rod.

Off gases from the reactor typically are around 280° C. and are cooled to a temperature by means of a cooling medium, preferably water cooled exchanger, at which dust filtration is conducted. This avoids the dust accumulation within the system and gas stream. The cooled gas, laden with the dust is filtered using sintered stainless steel filter elements to capture particles generated via homogeneous nucleation. Thus, the resulting filtered gases are non-contaminated with the dust for further recycle.

The off gas is further cooled for compression to the CVD recycle system pressure to recycle back to the system. The off gas temperature is maintained at about room temperature by means of an exchanger, preferably a water exchanger. The recycle hydrogen compressor is, in preferred embodiments, a two-stage, nonlubricated, balanced-opposed, reciprocating compressor. A non-lubricated reciprocating compressor is preferable in that it will circulate a large volume of gas with essentially no contamination. An ordinarily skilled artisan would understand that any compressor providing such qualitites may be used in embodiments of the invention. A two-stage compressor further limits the discharge temperature of the gas from each stage. Thus, in some embodiments, a maximum gas temperature is set by the temperature limitations of the Teflon rings and rider bands used in the compressor. A lower discharge temperature also favors longer compressor valve life and reliability. The off gas is then compressed to feed gas pressure to overcome across the CVD reactor pressure drop plus the pressure drop across the system. The discharge gas from the compressor is further cooled for further purification, recovery and recycle.

The hydrogen stream from the compressor aftercooler is further cooled by passing through interchangers using the cold hydrogen stream from the adsorbers/hydrogen purifier column as the cooling medium. The outlet gas is then finally cooled via liquid nitrogen (or proper cooling medium) closer to off gas impurity components condensation temperature. Preferably in a liquid nitrogen cooled exchanger. At such temperatures, most (at least about 95%) of the silane (including impurities) in the hydrogen stream is condensed. The condensed silane plus impurities stream may then be sent to a scrubber or can be flared or repurified or recycled.

The hydrogen stream after separation is separated from the mist and passed through one or more purification columns. The purification process is conducted at very low temperatures (at least around −170 to −175° C.) especially in the activated carbon bed with activated carbon having surface area greater than 500 m2/g or moleculer sieve beds. Generally, the purification columns, or adsorption beds, through which the hydrogen gas is passed are operated in series. Impurities in the hydrogen gas, such as argon, carbon compounds (mainly methane), uncondensed silane, boron and phosphorous compounds are retained in the adsorption bed. These beds may be regenerated selectively during which off gases may be flared, or otherwise disposed.

The purified very low temperature hydrogen, is passed through a cryogenic filter (preferably having a pore size 1 micron absolute size), to trap any particulates escaped from the adsorption beds. The hydrogen stream is then heated to about room temperature by passing the hydrogen stream through the previous hydrogen interchanger (thereby exchanging heat with the hot unpurified hydrogen). A final filtration of the high purity hydrogen gas is achieved in a recycle hydrogen filter (preferably having a pore size of 0.04 microns or less).

### The System

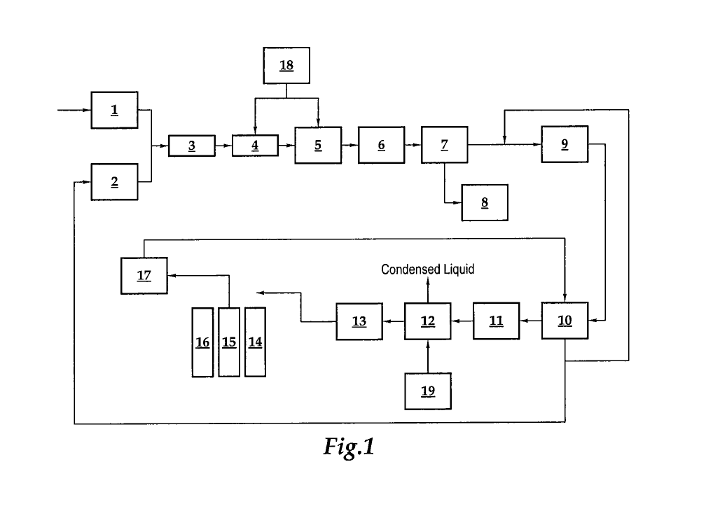

Referring to FIG. 1, the system of one embodiment of the invention is shown in schematic form. Table 1 below provides names for the components of the system shown in FIG. 1.

TABLE 1

| | |
|---|---|
| 1. | Silane supply |
| 2. | Hydrogen supply |
| 3. | Mixing tee |
| 4. | Preheater/exchanger |
| 5. | CVD reactor |
| 6. | Reactor outlet gas cooler |
| 7. | Dust filter |
| 8. | Dust hopper |
| 9. | Compressor |
| 10. | Recycle Hydrogen interchanger |
| 11. | Recycle Hydrogen cooler |
| 12. | Condenser |
| 13. | Knock-out drum |
| 14. | Hydrogen purifier (adsorption |
| | bed) |
| 15. | Hydrogen purifier (adsorption |
| | bed) |
| 16. | Hydrogen purifier (adsorption |
| | bed) |
| 17. | Cryogenic filter |
| 18. | Heating medium supply |
| 19. | Cooling medium supply |

In a typical operation, the silane is supplied to the storage tank [1] via exchanger. The silane is mixed with the hydrogen supplied from the system [2] by means of a static mixer [3]. The silane and hydrogen are heated to the feed temperature between 240-300° C. (i.e., below the silane decomposition temperature) via heat exchanger [4] before feeding into the reactor. The hydrogen dilution may be between about 85% and 99%+. The silane reacts and decomposes in the CVD reactor [5] to produce chunk polysilicon via heterogeneous reaction. Homogeneous reaction may also occur which competes to produce the silicon powder. The typical off gas contains dust, unconverted silane and other impurities. The off gas exits the reactor at temperatures typically about 260-280° C.

The off gas is further cooled in a water cooled exchanger [6] to about 175° C. The off gas, laden with dust, is filtered using sintered stainless steel filter elements [7]. The dust collects on the outside of these elements and is periodically removed by back pulsing the elements with recycle hydrogen. The dust falls from the elements and is collected in a drum [8] via hopper. It can also be collected directly in the super sack in alternative embodiments of the inventive system.

The filtered off gas is further cooled closure to the ambient condition (say about 30-35° C.) in a water cooled exchanger (not separately illustrated). The water cooled exchanger may be part of the compressor, which may include a recycle compressor inlet cooler, coarse filter, polishing filter, first stage suction bottle and a first stage discharge bottle. The cooled off gas is then optionally passed through a guard filter (not shown) to the recycle hydrogen compressor [9]. The recycle hydrogen compressor [9] may be in some embodiments, but is not limited to in all embodiments, a two-stage, non-lubricated, balanced-opposed, reciprocating compressor. Recycle hydrogen compressor [9] operation limits the discharge temperature of the gas from each stage to under about 130 to 135° C. The gas enters compressor [9] at about 6 psig and is compressed to about 28 psig in the first stage of compressor [9]. The gas discharged from the first stage of compressor [9] is then cooled from about 120 to about 125° C. to about 30 to about 38° C. using a compressor intercooler (not separately depicted) followed by a final polishing filter which may be part of the hydrogen compressor [9] (not separately shown). A single stage compressor can also be used with appropriate discharge and temperature controls in alternative embodiments of the inventive system

The hydrogen stream exiting the compressor is then cooled to −160 to −165° C. by passing through interchangers [10] using the cold hydrogen stream from the adsorbers [14, 15, 16] as the cooling medium. The hydrogen stream is further cooled to −170 to −180° C. in a liquid nitrogen cooled exchanger [11] and condenser [12]. A knockout pot [13] is provided to separate the condensed silane and other condensates (such as impurities) from the hydrogen stream. The separated silane may then be vaporized in an air-heated vaporizer (not shown) and fed to the silane compressor to be re-purified. If recovery of the silane is not desired, then the condensed silane stream may be sent to a scrubber and flared or otherwise disposed.

A separated hydrogen gas stream exits from the top of the knockout drum [13] and flows up through an optional demister (not separately depicted) and passes through adsorption beds preferably, operating in series [14-16]. In preferred embodiments, adsorption beds [14-16] are carbon beds. Impurities in the hydrogen gas such as argon, carbon compounds (mainly methane), uncondensed silane, boron and phosphorous compounds are typically retained in the first carbon bed.

The adsorption beds [14-16] are generally regenerated (using pressure and temperature swings methods) with the time between regenerations influenced by silane conversion in the reactor and the efficiency of the silane condensation in the exchangers. In a preferred embodiment, the regenerated column is lined up and brought back online downstream of the other columns so that a freshly regenerated column is the last column in the series and the last column to contact the recycle gas. When such a regeneration scheme is utilized, the secondary adsorption bed may then be taken off line and regenerated.

The purified hydrogen exiting the adsorption beds [14-16] is at about −170-175° C. and is then passed through a cryogenic filter [17] which has a gas rating of 1 micron absolute or lower, to trap any particulates from the adsorption beds [14-16]. The hydrogen stream is then heated to about 25-30° C. by passing through the tube-side of the interchangers [10]. A final filtration of the high purity hydrogen is achieved in the recycle hydrogen filter (not shown) which contains elements rated at 0.1-0.04 microns. This finally filtered and purified hydrogen stream is recycled back to the reactor [5].

The hydrogen supply system is the hydrogen source which supplies hydrogen to the reactors [5] in the event of a recycle compressor shutdown or as make-up hydrogen during times when leakage losses in the recycle loop occur. The hydrogen supply system is designed to provide enough time to restore compressor operation or to shutdown the reactors orderly when compressor operation is disrupted.

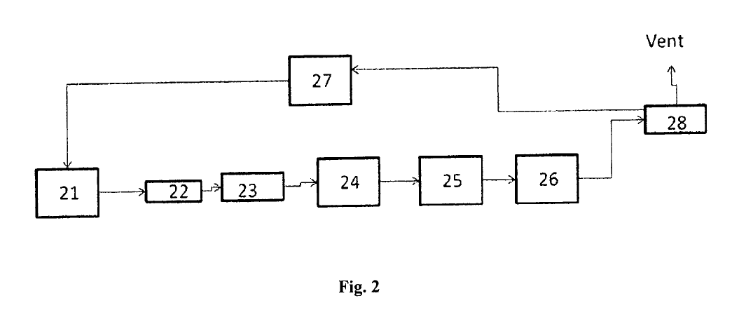

A typical cooling system (nitrogen) for silane impurities separation is shown in FIG. 2. Table 2 below provides names for the components of the system shown in FIG. 2. The liquid nitrogen may be flowed through the cryogenic filter [22] to gas filter [23] and then to the silane condenser [24] for separation of hydrogen and condensable gas. In some embodiments of the invention, the liquid nitrogen is used for cooling and flowed through the recycle hydrogen cooler (not shown) and hydrogen regeneration cooler [26] as a cooling medium. The nitrogen off gas is then warmed and discharged to the vent, first passing through vent heater [28] or recycled to compressor [27].

TABLE 2

| | |
|---|---|
| 21. | Liquid Nitrogen storage |
| 22. | Filter |
| 23. | Gas Filter |
| 24. | Silane Condenser |
| 25. | Recycle Hydrogen Cooler |
| 26. | Hydrogen regeneration Cooler |
| 27. | Compressor |
| 28. | Vent Heater |

We claim:

1. In a CVD-Siemens system including a reactor vessel containing at least one reaction chamber surrounded by a jacket, wherein a pre-heating fluid is circulated in the jacket; one or more electrode assemblies extending into the reaction chamber wherein each electrode assembly comprises a gas inlet, one or more heat transfer fluid inlets/outlets; at least one pair of silicon filaments, the filaments connected to each other at their upper ends with a silicon bridge to form a filament/slim rod assembly, each filament/slim rod assembly enclosed in an isolation jacket; a source of a silicon-bearing gas connected to the interior of the vessel for supplying the gas into the reaction chamber, wherein the reaction chamber includes one or more distributor locations, to produce a reaction and to deposit polycrystalline silicon on the filaments by chemical vapor deposition thereby producing a rod of polycrystalline silicon; a heat transfer system connected to the jacketed reaction chamber to supply heat transfer fluid to preheat the filaments/slim rod assemblies; and a power supply, the improvement comprising a hydrogen recovery and recycle system comprising: a liquid Nitrogen cooling system; a silane condenser; a recycle hydrogen cooler; and a Hydrogen regeneration cooler, a compressor, and one or more interchangers wherein the discharged gas from the reactor is cooled to between about 30 and 40° C., the compressor accepts and compresses the cooled gas to the system requirement pressure, the interchangers cool an off-gas to between −160 and −165° C. using counter flow between cooler and warmer streams, the off-gas stream is further cooled to between −170 and −180° C. using a liquid nitrogen exchanger in the hydrogen regeneration cooler.

2. The improvement of claim 1 further comprising a knockout drum to accept the gas from the recycle hydrogen cooler wherein a first purified hydrogen gas is separated from silane and impurities and collected from the top of the knockout drum.

3. The improvement of claim 2 further comprising one or more adsorption beds arranged after the knockout drum wherein the hydrogen stream flows through the adsorption beds such that the adsorption beds remove impurity gasses from the hydrogen stream to produce a purified hydrogen stream.

4. The improvement of claim 3 wherein there are two or more adsorption beds arranged in series and producing the purified hydrogen stream.

5. The improvement of claim 3 further comprising a cryogenic filter through which the second purified hydrogen stream is passed to remove fine particles to produce a final purified hydrogen stream.

6. The improvement of claim 5 further comprising means to recycle the final purified hydrogen stream to the reactor.

7. The improvement of claim 1 further comprising a hydrogen storage system.

8. The improvement of claim 1 further comprising a make-up hydrogen supply system.

9. A method for recovery, purification and recycle of hydrogen in a CVD Siemens process comprising:
collecting off gases from a CVD Siemens process reactor;
cooling the off gases;
filtering the off gases;
compressing the off gases to at least about 25 psig;
cooling the compressed off gases to a temperature between about −160 C and −165 C and then cooling the compressed off gases againt to a temperature between about −170 C and −180 C thereby separating condensed impurities from a hydrogen component of the off gases;
passing the hydrogen component through absorption beds to remove any argon, hydrocarbons, uncondensed silanes, boron and phosphorous compounds from the hydrogen component to obtain a first filtered hydrogen stream;
cryogenically filtering the first filtered hydrogen stream to produce a second filtered hydrogen stream;
heating the second filtered hydrogen stream to between about 25 C and 30 C to produce a high purity hydrogen stream;
passing the high purity hydrogen stream through a recycle hydrogen filter to remove particles having a size between 0.1 and 0.4 microns to produce a final hydrogen recycle stream; and
recycling the final hydrogen recycle stream to the CVD Siemens process reactor.
